(19) United States
(12) Patent Application Publication
(10) Pub. No.: US 2014/0138125 A1
(43) Pub. Date: May 22, 2014

(54) CIRCUIT BOARD AND METHOD OF MANUFACTURING THE SAME, TOUCH PANEL SENSOR SHEET AND SCREEN PRINTING PLATE

(71) Applicant: NIPPON MEKTRON, LTD., Tokyo (JP)

(72) Inventors: Masayuki Iwase, Tokyo (JP); Kazuyuki Ozaki, Tokyo (JP)

(73) Assignee: NIPPON MEKTRON, LTD., Tokyo (JP)

(21) Appl. No.: 14/064,581

(22) Filed: Oct. 28, 2013

(30) Foreign Application Priority Data
Nov. 16, 2012 (JP) 2012-251779

(51) Int. Cl. H05K 1/09; H05K 3/12

(52) U.S. Cl. CPC H05K 1/092; H05K 3/1233; H05K 3/1225
USPC 174/251; 101/129; 174/257; 174/253; 101/127

(57) ABSTRACT

Disclosed is a method of manufacturing a circuit board, which includes a stand-by process setting a screen printing plate so as to be opposed with a base, where the screen printing plate has a line pattern formed therethrough, and the line pattern is configured by a plurality of dot-like through-holes discretely pierced and arrayed in a single line; a coating process coating an ink which contains a water-dispersed electroconductive paste onto the surface of the screen printing plate; and an ejection process ejecting ink dots through the dot-like through-holes onto the surface of the base, by pressing the screen printing plate into the base under sliding contact of a squeegee with the surface of the screen printing plate, and allowing the ink dots ejected out from the adjacent through-holes to fuse on the surface of the base, to thereby form a linear ink puddle.

This application is based on Japanese Patent Application No. 2017-251779, the content of which is incorporated herein to by reference.

### BACKGROUND

1. Technical Field

The present invention relates to a circuit board having an electroconductive pattern formed on the surface of a base, a method of manufacturing the same, a touch panel sensor sheet having the circuit board, and a screen printing plate.

2. Related Art

In recent years, there has been a sharply increasing demand for a touch panel as disclosed in JP-A-2011-054122, as handheld devices such as smartphones become widespread. With the touch panel of the electrostatic capacitance type described in JP-A-2011-054122, implemented is a so-called, multi-touch function by which gestures of two or more fingers may slide screen contents, or steplessly enlarge or shrink them. There are known various configurations of sensor sheets used for the electrostatic capacitance type touch panel. Specific examples include those having X- and Y-sensor patterns formed respectively on both surfaces of a translucent base such as an organic film or glass plate, those configured by forming X- and Y-sensor patterns respectively on two translucent bases and then bonding the bases, and those configured by forming X- and Y-sensor patterns on one surface of a translucent base. Among them, the sensor sheet having the X- and Y-sensor patterns formed on one surface of a translucent base includes a transparent insulating material at the intersections of the transparent X- and Y-sensor patterns so as to avoid short-circuiting of the both.

In a touch panel sensor sheet described in JP-A-2011-243928, either one of the X- and Y-sensor patterns (X-sensor pattern, for example) is formed in an indiscrete manner, and the other sensor pattern (Y-sensor pattern, for example) is formed in a discrete manner. The discretely formed portions of the sensor pattern are bridged by a jumper structure composed of a transparent electroconductive pattern. More specifically, a part of the X-sensor pattern is covered with a transparent insulating material, and on the transparent insulating material, the transparent electroconductive pattern which extends in the Y-direction is formed. In this way, the discretely formed portions of the Y-sensor pattern are bridged. The transparent insulating material will be referred to as “transparent insulating pattern” or “jumper pattern”, hereinafter. In recent years, for the purpose of improving visible light transmissivity of the touch panel sensor sheet, efforts have been made on forming the transparent electroconductive pattern, by using transparent electroconductive materials in place of metal materials, relatively with smaller line widths. Published Japanese Translation of PCT International Publication for Patent Application No. 2002-500405 proposes use of a water-dispersed electroconductive paste such as polyethylene dioxythiophene (PEDOT) paste as the transparent electroconductive material, which is patterned by screen printing into a desired shape.

### SUMMARY

The PEDOT paste has a very large surface tension since water is used as a part of the solvent thereof, and it is therefore difficult to ensure a sufficient level of wettability on the surface of the underlying layer. In particular, for the case where the underlying layer is composed of a plurality of different materials including those for transparent insulating pattern, X- and Y-sensor patterns and so forth, the PEDOT paste will exhibit different levels of wettability from part to part on the underlying layer, making it difficult to form a thin-line jumper pattern in a stable manner. More specifically, an effort of forming the thin-line jumper pattern will result in fluid migration of the PEDOT pate in the middle of line, proving it difficult to form the jumper pattern with dimensions precisely as designed.

This sort of problem which possibly arises in the process of forming the electroconductive pattern is not an issue for the touch panel only. In recent years, many of electronic devices are required to have flexible substrates and shrunk electroconductive pattern, and in pursuit of formation of the electroconductive pattern with high quality and precise dimensions as designed.

The present invention was conceived in consideration of the problems described above, and is to provide a method of manufacturing a circuit board capable of forming a narrow-width electroconductive pattern with precise dimensions as designed, even if the transparent electroconductive material used herein has a large surface tension and can ensure a sufficient level of wettability on the printing base only with difficulty, just as exemplified by the PEDOT paste. The present invention is also to provide a circuit board manufacture by the method, and a screen printing plate used for the method of manufacturing.

According to the present invention, there is provided a method of manufacturing a circuit board, the method includes:

establishing stand-by by setting a screen printing plate so as to be opposed with a base, the screen printing plate having a line pattern formed therethrough, and the line pattern being configured by a plurality of dot-like through-holes discretely pierced and arrayed in a single line or in a plurality of lines;

coating an ink which contains a water-dispersed electroconductive paste into the surface of the screen printing plate;

ejecting the ink through the dot-like through-holes onto the surface of the base, by pressing the screen printing plate onto the base under sliding contact of a squeegee with the surface of the screen printing plate, and allowing ink dots ejected out from the adjacent through-holes to fuse on the surface of the base, to thereby form a linear ink puddle; and

drying the linear ink puddle to form an electroconductive pattern on the surface of the base.

According to the present invention, there is provided a circuit board which includes an electroconductive pattern composed of an organic electroconductive polymer, formed in a line pattern. The electroconductive pattern has dense areas and sparse areas alternately disposed repetitively in the longitudinal direction of the electroconductive pattern. The dense areas have, when counted in the widthwise direction, a large number of grains of the organic electroconductive polymer, and the sparse areas have a small number of grains.

According to the present invention, there is provided a touch panel sensor sheet which includes the circuit board described above. The base includes a flexible transparent sheet composed of a visible: light transmissive material; and a first electrode and a second electrode, which configure a first underlying area, and an insulating pattern which configures a second underlying area, both areas are formed on one surface of the transparent sheet. The first electrode contains a plurality of first electrode patterns arrayed repetitively in a first direction and connected with each other, and the second electrode contains a plurality of second electrode patterns arrayed in a second direction which crosses the first direction, while being spaced from the first electrode patterns. The insulating pattern covers an interconnect between the adjacent first electrode patterns, and the electroconductive pattern is formed above the interconnect, so as to configure a jumper pattern which connects the adjacent second electrode patterns.

According to the present invention, there is provided a screen printing plate having a line pattern formed therethrough. The line pattern is configured by a plurality of dot-like through-holes discretely pierced and arrayed in a single line or in a plurality of lines.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a schematic plan view illustrating a screen printing plate according to an embodiment of the present invention, and FIG. 1B is an enlarged view of area B in FIG. 1A;

FIG. 2A is a drawing explaining a coating process, FIG. 2B is a drawing explaining an election process, FIG. 1C is a partial enlarged view of FIG. 2B, and FIG. 2D is a drawing explaining a drying process;

FIG. 3 is a schematic plan view schematically illustrating an electroconductive pattern;

FIG. 4A is a schematic drawing illustrating a touch panel sensor sheet manufactured by the method of the present invention, and FIG. 4B is an enlarged view of area B in FIG. 4A;

FIG. 5 is a cross sectional schematic drawing of the touch panel sensor sheet taken along the Y-axis;

FIG. 6A is a schematic drawing of a line pattern, and FIG. 6B is a schematic drawing illustrating a patterned electroconductive pattern;

FIG. 7A is a schematic drawing illustrating a line pattern configured by through-holes arrayed in a plurality of lines to for a grid, and FIG. 7B is a schematic drawing of an obtained electroconductive pattern;

FIG. 8A is a schematic drawing illustrating a line pattern configured by through-holes arrayed in a plurality of lines in a staggered manner, and FIG. 8B is a schematic drawing of an obtained electroconductive pattern;

FIG. 9A is a schematic drawing illustrating a first modified example of the screen printing plate, and FIG. 9B is a schematic drawing illustrating an electroconductive pattern formed on a base;

FIG. 10A is a schematic drawing illustrating a second modified example of the screen printing plate, and FIG. 10B is a schematic drawing illustrating an electroconductive pattern formed on the base;

FIG. 11A is a microphotograph showing an electroconductive pattern of Example 1, and FIG. 11B is a microphotograph showing an electroconductive pattern of Example 2; and

FIG. 12A is a microphotograph showing an electroconductive pattern of Example 3, and FIG. 12B is a microphotograph showing an electroconductive pattern of Example 4.

### DETAILED DESCRIPTION

The invention will be now described herein with reference to illustrative embodiment. Those skilled in the art will recognize that many alternative embodiments can be accomplished using the teachings of the present invention and that the invention is not limited to the embodiments illustrated for explanatory purposes.

Embodiments of the present invention will now be explained referring to the attached drawings. Note that, in all drawings, all similar constituents will be given similar reference numerals or symbols, and the explanation will not always be repeated. The explanation will be made in some cases while defining the upward and downward directions, merely for the purpose of explaining relative positional relations among the constituent for convenience, without always meaning the vertical direction of gravity.

The method of manufacturing a circuit board according to an embodiment of the present invention (occasionally referred to as “the present method”, hereinafter) will be explained while dividing it into a plurality of steps in some cases, the order of description of which will not always restrict the order or timing of implementation of the individual steps. When the present method is implemented, the order of the plurality of steps may be modified without adversely affecting the gist, and a part of or entire portion of the timing of implementation of the plurality of steps may overlap.

First, a screen printing plate 10 used in the present method will be outlined.

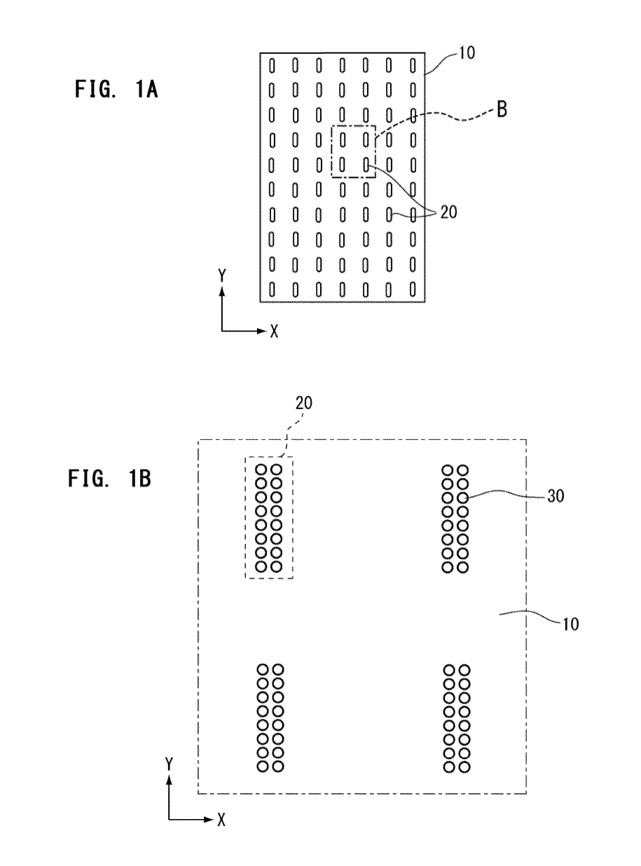

FIG. 1A is a schematic plan view illustrating the screen printing plate 10 according to an embodiment of the present invention. FIG. 1B is an enlarged view of area B in FIG. 1A. The present method is implemented by using the screen printing plate 10 of this embodiment.

The screen printing plate 10 of this embodiment characteristically has line patterns 20 formed therethrough, and each line pattern 20 is configured by a plurality of dot-like through-holes 30 discretely pierced and arrayed in a single line or in a plurality of lines. As illustrated in FIG. 1B, in the screen printing plate 10 of this embodiment, one line pattern 20 is configured by through-holes 30 arrayed in two lines in the direction of the X-axis. The individual line patterns 20 are extended in the direction of the Y-axis. The screen printing plate 10 of this embodiment has a large number of line patterns 20 each having a form of line segment.

The line pattern herein has a liner or curved oblong geometry, characterized by the longitudinal dimension larger than the widthwise dimension. Each line pattern 20 of this embodiment corresponds to an area occupied by an assembly of a plurality of through-holes 30 discretely formed and arrayed in a single line or in a plurality of lines.

Material and dimension of the screen printing plate 10 are not specifically limited. For example, the thickness may be 10 μm or larger and 200 μm or smaller, and more preferably 20 μm or larger and 50 μm or smaller. A metal mask is preferably used as the screen printing plate 10 of this embodiment. The line pattern 20 may be formed in the screen printing plate 10, by any method selectable from etching, laser working and electroforming (additive process). From the viewpoint of dimensional and positional accuracies of the through-holes 30, also the mask pattern may be formed by the additive process on the screen printing plate 10. Material for composing the screen printing plate 10 is exemplified by nickel-based alloys. Alternatively, also a screen mesh, configured by a metal mesh fabric with a part of openings thereof stopped with an emulsion, is usable as the screen printing plate 10. The metal mask is, however, used more suitably from the viewpoint of stability in the amount of election of ink, since the opening have neither weft nor warp exposed therein, unlike the openings of fabric.

The line pattern 20 is configured by the through-holes 30 arrayed in a single line or in a plurality of lines. In this embodiment, the through-holes 30 are arrayed in a plurality of (N) lines in the widthwise direction. In the longitudinal direction of line, there are arrayed through-holes 30, where the number of arrayed holes is larger than that (N) in the widthwise direction.

While FIG. 1B illustrates an exemplary case where eight through-holes 30 are arrayed in the direction of the Y-axis to thereby configure the line pattern 20, the number of arrayed through-holes 30 is arbitrary.

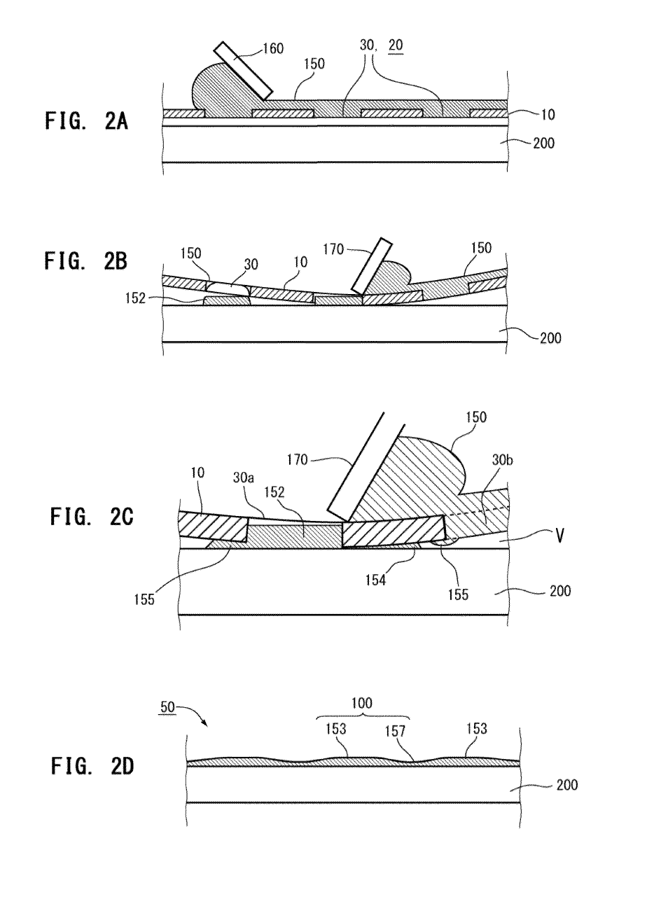

Next, the present method will be outlined referring to FIG. 2A to FIG. 2D. FIG. 2C is a partial enlarged view of FIG. 2B. The present method relates to a method of manufacturing a circuit hoard 50.

The present method includes a stand-by step, a coating step (FIG. 2A), an ejection step (FIG. 2B), and a drying step (FIG. 2D).

In the stand-by step, the screen printing plate 10, which has line patterns 20 formed therethrough, each line pattern 20 being configured by a plurality of dot-like, through-holes 30 discretely pierced and arrayed in a single line or in a plurality of lines, is set so as to be opposed with a base 200. The direction of arrangement of the through-holes 30, that is, the direction in which the line patterns 20 extend, agrees with the rightward direction in FIG. 2A. In the coating step, an ink 150 which contains a water-dispersed electroconductive paste is coated over the screen printing plate 10. The ink 150 is coated using a scraper 160. Action of coating of the ink 150 using the scraper 160 refers to “scraper coating”.

In the ejection step, a squeegee 170 is brought into sliding contact with the surface of the screen printing plate 10, and thereby the screen printing plate 10 is pressed onto the base 200. By the action, the ink 150 applied by scraper coating is ejected out from the dot-like through-holes 30 onto the surface of the base 200 to form in dots 152, and the ink dots 152 elected out from the adjacent through-holes 30 are allowed to fuse on the surface of the base 200, to thereby form a linear ink puddle. The ink dots 152 fused to form the linear in puddle are shown in FIG. 2D. In the drying step, the linear puddle of ink 150 is dried, to thereby form the electroconductive pattern 100 on the surface of the base 200.

According to the present. method, it is now possible to form a narrow-width electroconductive pattern with high quality, even when an electroconductive ink used herein has a large surface tension and can ensure a sufficient level of wettability on the printing base only with difficulty.

Next, the present method will be explained in further detail.

The screen printing plate 10 used in the present method is a metal mask. in the stand-by step illustrated in FIG. 2A, the screen printing plate 10 is stretched under tension using a jig or screen printing apparatus (not illustrated), so as to be opposed with the base 200 while keeping a slight clearance in between. The clearance is generally set to a size which is only ignorable as compared with the length of edges of the screen printing plate 10, and larger than the thickness of the screen printing plate 10.

The ink 150 used in the coating step of the present method contains a water-dispersed electroconductive paste as a main ingredient. The water-dispersed electroconductive paste is configured by an organic electroconductive polymer dispersed in a water-based solvent.

The organic electroconductive polymer is exemplified by PEDOT (polyethylene dioxythiophene) polyaniline and polypyrrole. From the viewpoint of stability of forming of the electroconductive pattern 100, PEDOT is particularly preferable. PEDOT generally refers to a product obtained by mixing PSS (polystyrene sultanate) into PEDOT, and is also denoted as PEDOT/PSS. In this patent specification, the mixture is simply referred to as PEDOT or PEDOT paste.

In the ejection step, the squeegee 170 is slid over the surface of the screen printing plate 10 while being brought into contact therewith. By the action, the ink 150 is pushed through the through-holes 30 out onto the base 200, whereas an extra ink 150 is scraped off. Since the screen printing plate 10 is elastic, so that the screen printing plate 10 bends and is pressed onto the base 200, under sliding contact of the squeegee 170 with the screen printing plate 10. Relation between the direction of travel of the squeegee 170 and the direction in which the line patterns 20 extend is arbitrary. The squeegee 170 may be allowed to travel in parallel with, or obliquely to the longitudinal direction of the line patterns 20. As illustrated in FIG. 2B, the ink 150 is ejected in the form of ink dots 152 onto the base 200, after passing through the through-holes 30 which are discretely pierced. A portion of the ink 150 may, as illustrated in the drawing, remain in the through-holes 30 in some cases. When the squeegee 170 passes over the through-holes 30, the screen printing plate 10 elastically restores to form the initial clearance between itself and the base 200. The portions of the ink 150 filled in the through-holes 30 is reduced in the viscosity under pressure applied by the squeegee 170, and adheres to the surface of the base 200. After the squeegee 170 passed over, the ink 150 remained on the surface of the base 200 forms the ink dots 152, with the viscosity recovered.

As illustrated in FIG. 2C and FIG. 2D, in the ejecting step, the ink 150 passes through a through-hole 30a, and creeps forward in the direction of sliding contact of the squeegee 170 into a gap V between the screen printing plate 10 and the base 200. Portions of the ink 150 which creep on the back surface of the screen printing plate 10 will generally be referred to as creeping ink, and in particular a portion of the ink which creeps forward in the direction of sliding contact of the squeegee 170 will be referred to as forward-creeping ink 154. The ink 150 will creep on the back surface of the screen printing plate 10, not only forward in the direction of sliding contact of the squeegee 170, but also backward and sideward. Such portions of the ink other than that creeps forward will be referred to as peripheral-creeping ink 155. The forward-creeping ink 154 which creeps out from the through-hole 30a fuses with the ink (ink dot 152) ejected out from another through-hole 30b (indicated by a broken line in FIG. 2C) which is forwardly adjacent thereto in the direction of sliding contact of the squeegee 170. More specifically, the forward-creeping ink 154 which creeps on the back surface ahead of the through-hole 30a fuses with the peripheral-creeping ink 155 which creeps behind another through-hole 30h which is forwardly adjacent thereto. There are two major reasons. The first reason is that, in the process of scraper coating illustrated in FIG. 2, the ink 150 elected out from the through-holes 30 slightly sneaks on the back surface of the screen printing plate 10, and therefore the peripheral-creeping ink 155 stays on the back surface so as to fully surround the through-holes 30. The second reason is that the ink 150 pressed under the squeegee 170 is reduced in the viscosity, so that the ink 150 elected out from the through-holes 30 creeps into the gap V to form the forward-creeping ink 154, with the aid of capillary force exerted on the gap V, and wettability on the screen printing plate 10 and the base 200. By an integral action of these events, the creeping ink principally fuses with the ink dot 152 which is forwardly adjacent thereto in the direction of sliding contact of the squeegee 170 (rightward in FIG. 2C). If the distance between the adjacent edges of the through-holes 30 were increased or decreased, the adjacent ink dots 152 may be fused in a successful manner, by appropriately adjusting various parameters. The parameters include diameter Dd, linewise pitch Pd and widthwise pitch Pw, thickness Tm of the screen printing plate 10, viscosity of the ink 150, and wettability of the surface of the base 200. The distance between the adjacent edges of the through-holes 30 in the longitudinal direction of line is given by Pd−Dd, and the distance between the adjacent edges of the through-holes 30 in the widthwise direction is given by Pw−Dd. The electroconductive pattern 100 may be formed either by fusing the ink dots 152 arrayed in the direction of sliding of the squeegee 170, or by fusing the ink dots 152 arrayed in the direction crossing to the direction of sliding. For the case where a plurality of line patterns 20 are formed in the widthwise direction of the screen printing plate 10, the ink dots 152 arrayed in such widthwise direction may be fused. In this way, from a plurality of line patterns 20, it is now possible to for the electroconductive patterns 100, the number of lines of which is smaller (by one, for example) than the number of lines of the plurality of line patterns 20. More specifically, also when the squeegee 170 is moved under sliding contact in the direction orthogonal to the direction in which the line patterns 20 extend, a continuous electroconductive pattern 100 may be formed by fusing the ink dots 152 arrayed along the line pattern 20. For the case where, as illustrated in FIG. 1B, the through-holes 30 are formed in a plurality of lines in the widthwise direction of each line pattern 20, a single line of electroconductive pattern 100 may also be formed by fusing the ink dots 152 respectively arrayed in the widthwise direction and in the longitudinal direction. The direction in which the ink dots 152 are fused and the direction of sliding of the squeegee 170 may agree, or may disagree. The squeegee 170 may alternatively be slid obliquely to the longitudinal direction of the line pattern 20, to thereby fuse the ink dots 152 respectively in the widthwise direction and in the longitudinal direction of the line pattern 20.

The ink (ink dot 152) ejected out from one through-hole 30 is preferably allowed to fuse with another portion of the ink (ink dot 152), based on diffusion with the aids of wettability on the surface of the base 200 and creepage on the back surface out from the through-holes 30. In this case, the adjacent ink dots 152 ejected onto the base 200 may be fused in a successful manner, by appropriately adjusting various parameters which include the diameter (Dd) of the through-hole 30, center-to-center distance (Pd, Pw) of the adjacent through-holes 30, the thickness (Tm) of the screen printing plate, the viscosity of the ink 150, rate of volatilization of solvent in the ink 150, pressing force of the squeegee 170 against the screen printing plate 10, and the wettability on the surface of the base 200.

More specifically, when a metal mask is used as the screen printing plate 10, the thickness (TM) of the screen printing plate 10, the diameter (Dd) of the through-hole 30, and the center-to-center distance (P1) of the through-holes 30 which are adjacent in the direction of travel of the squeegee 170 may be set so as to satisfy Formula (1) below. In the formula, the right side of the formula means that the adjacent through-holes 30 are spaced from each other.

2.5×Tm≧P1−Dd>0 Formula (1)

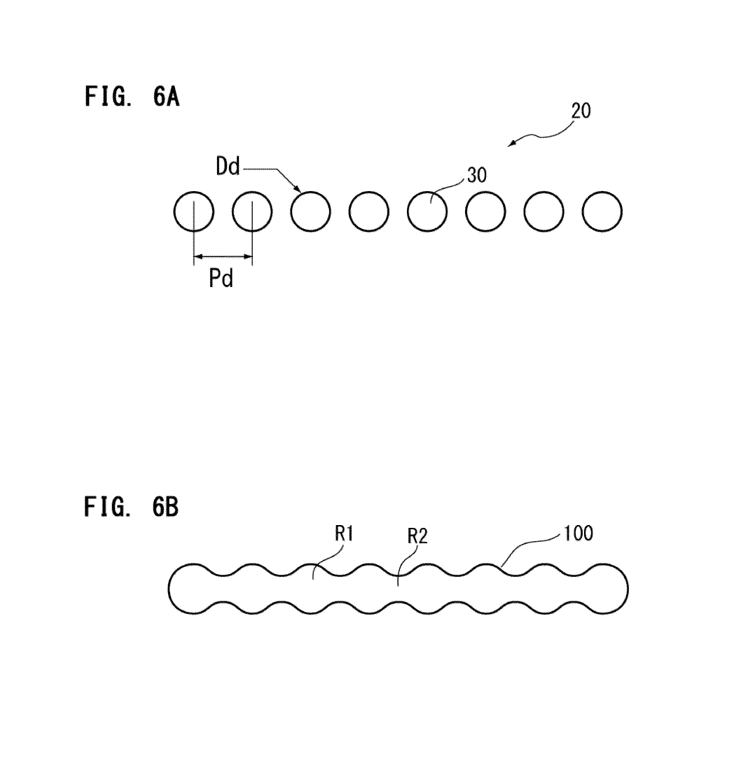

Now, for the case where the squeegee 110 is allowed to travel in the direction in which the line patterns 20 extend, the center-to-center distance (P1) agrees with the linewise pitch (Pd). For the case where the squeegee 170 is allowed to travel in the widthwise direction of the line patterns 20, the center-to-center distance (P1) agrees with the widthwise pitch (Pw) (see FIG. 6A to FIG. 8B for Dd, Pd and Pw).

The center-to-center distance (P2) of the through-holes 30 adjacent in the direction orthogonal to the direction of travel. of the squeegee 170 may be determined so as to satisfy Formula (2) below:

1.5×Tm≧P2−Dd>0 Formula (2).

The linewise pitch (Pd) may be determined so as to satisfy Formula (3) below. When determined as above, the screen printing plate 10 may be processed in a successful manner.

Pd−Dd≧Tm Formula (3)

The linewise pitch (Pd) may be determined so as to satisfy Formula (4) below:

Pd>2×Tm Formula (4).

Assuming now that the through-hole 30 is circular, the diameter (Pd) means the diameter of the through-hole 30. If the through-hole 30 is not circular, the diameter is given by an average of the widthwise dimension of the through-holes measured in cross. sections, taken along a line which passes the centers of gravity of the through-holes 30 and extends in the longitudinal direction of the line pattern 20. The center-to-center distance (Pd) of the through-holes 30 is given by an average of the distance between the centers of gravity (face centers) of the adjacent through-holes 30.

Referring to the Formulae (1) and (2), it is understood that as the thickness (Tm) of the screen printing plate 10 is set large, the adjacent ink dots 152 will remain fusable with each other, even if the values of distance (P1−Dd) and (P2−Dd) between the adjacent edges of the through-holes 30 increase.

Referring to the Formula (4), thickness of undried ink dot. 152 is equivalent to the thickness (Tm) of the screen printing plate 10. When the electroconductive pattern 100 is formed by using the ink 150 mainly composed of an organic electroconductive polymer, electric resistance of the electroconductive pattern 100 may be suppressed to a desired level or below by suppressing the thickness (Tm) of the screen printing plate 10 and increasing the diameter (Dd), and not only the electroconductive pattern 100, but also the circuit board 50 may be improved in the flexibility by the thin film effect. In this case, it is recommendable to set the diameter (Dd) and the thickness (Tm) of the screen printing plate 10, so as to satisfy Formula (5) below:

Diameter (Dd)≧Thickness (Tm) of screen printing plate 10 Formula (5).

In the present method, the ink 150 is coated using the screen printing plate having formed therein a plurality of dot-like openings smaller than the design dimension of the electroconductive pattern 100, rather than using a screen printing plate with a dimension of openings equal to the design dimension of the electroconductive pattern 100. The electroconductive pattern 100 is converted to an assembly of discrete dots, the ink dots 152 are formed at the position of the dots, and the ink dots 152 are then fused to form the electroconductive pattern 100. By coating the ink 150 so as to be diversified into a large number of ink dot 152, a possible range of liquid migration of the ink 150 coated on the base 200 may be restricted within the individual dots. In addition, since the adjacent ink dots 152 may be fused by virtue of proximity of the through-holes 30, the electroconductive pattern 100 is ensured to have electro-conductivity. According to the present method, a single electroconductive pattern 100 of a desired dimension may be formed by piercing a large number of through-holes 30 in a plurality of lines, depending on a desired widthwise dimension of the electroconductive pattern 100 to be produced, and by fusing the ink dots 152 arrayed in the plurality of lines in the widthwise direction and the longitudinal direction. The linear electroconductive pattern 100 means that the length thereof is larger than the width, typically characterized by a ratio of the length to the width of 3 or larger. Dimensions of the electroconductive pattern 100 is not specifically limited. The widthwise dimension of the electroconductive pattern 100 may be 10 μm or larger, and even may be 1 mm or larger. For example the length may be 500 μm or longer, the width may be 100 μm or wider, and the ratio of length and width may be 5 or larger.

As illustrated in FIG. 1B, the present method relates to a method of manufacturing the circuit board 50 using the screen printing plate 10 which has the line patterns 20 formed therethrough, each line pattern 20 being configured by a plurality of through-holes 30 arrayed in a plurality of lines laid in the widthwise direction. In the election step, the ink (ink dots 152) elected out from the through-holes 30 arrayed in the widthwise direction is characteristically fused with each other to form a single linear ink puddle.

As illustrated in FIG. 2D, the thus-formed electroconductive pattern 100 may have different final thicknesses in an ink dot area 153 corresponded to the through-holes 30 and in a crept ink (forward-creeping ink 154, peripheral-creeping ink 155) area 157 corresponded to the gaps V. The crept ink area 157 is an area formed after the forward-creeping ink 154 and the peripheral-creeping ink 155 fuse with each other, leveled, and then dried up while partially reducing difference of height between itself and the ink dot area 153. By using the ink 150 with low viscosity, the difference of height between the ink dot area 153 and the crept ink area 157 may be reduced or cleared.

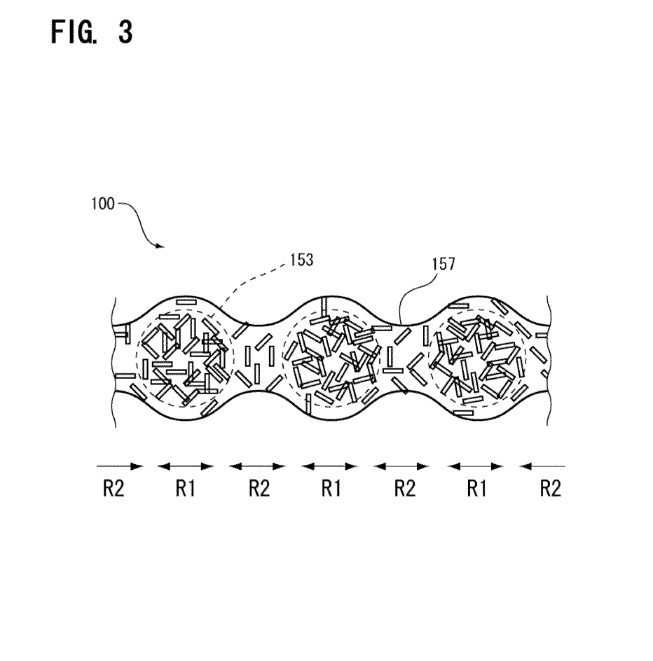

FIG. 3 is a schematic plan view schematically illustrating the electroconductive pattern 100 formed by the present method. According to the present method, manufactured is the circuit board 50 having the electroconductive patterns 100, composed of an organic electroconductive polymer, formed in lines on the surface of the base 200. In each electroconductive pattern 100, dense areas R1 each having a large number of grains of the organic electroconductive polymer counted in the widthwise direction thereof (up-and-down direction in FIG. 3), and sparse areas R2 each having a small number of grains, are arranged alternately and repetitively in the longitudinal direction of the electroconductive pattern 100 (lateral direction in FIG. 3). The circuit board 50 of this embodiment has the structure excellent in stability of manufacturing of the electroconductive patterns 100, so that the narrow-width electroconductive patterns 100 may be implemented with a high yield. Each dense area R1 corresponds to each ink dot 152 ejected in the election step at a position just below each through-hole 30. In other words, the dense area R1 corresponds to the ink dot area 153. In FIG. 3, the dense area R1 and the sparse area R2 are illustrated while emphasizing the difference in the line width. The ejected ink dots 152 are leveled with time, and thereby the difference in the line width decreases. Each sparse area R2 corresponds to the crept ink (forward-creeping ink 154, peripheral-creeping ink 155) crept in the ejection step out from each through-hole 30 into the gap V. In other words, the sparse area R2 corresponds to the crept ink area 157. In an undried state of the electroconductive patterns 100, the crept ink area 157 is higher in ratio of solvent with high fluidity, and lower in ratio of organic electroconductive polymer such as PEDOT, as compared with ink dot area 153. In other words, in a plan view of the dried electroconductive pattern 100, the ink dot area 153 has a larger number of grains of organic electroconductive polymer in unit area as compared with the crept ink area 157. The ink dot area 153 has a larger number of grains of the organic electroconductive polymer per unit length in the widthwise direction of each electroconductive pattern 100, as compared with the crept ink area 157. Abundance of the grains of the organic electroconductive polymer may be confirmed by optical observation of the electroconductive patterns 100.

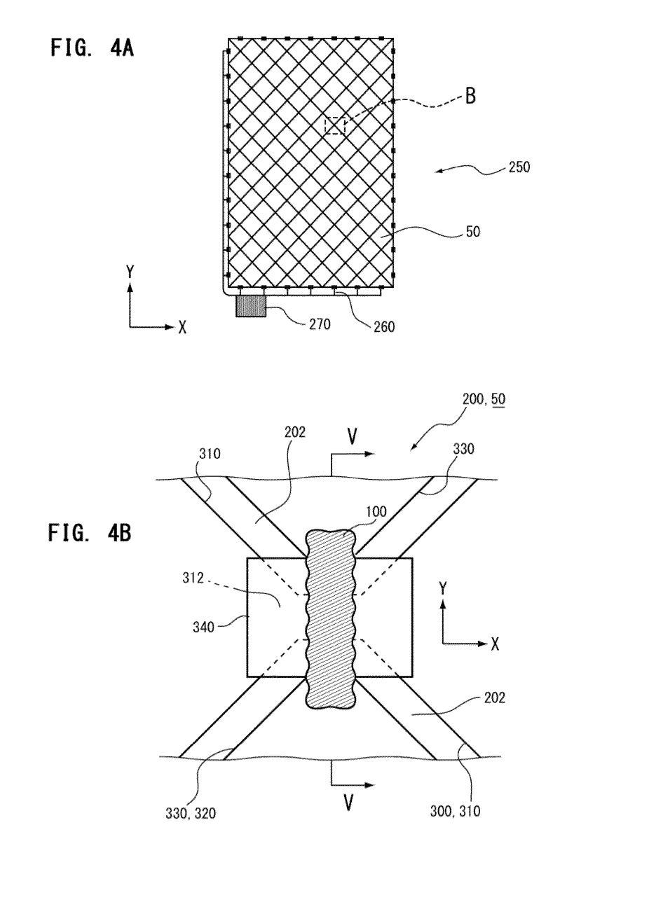

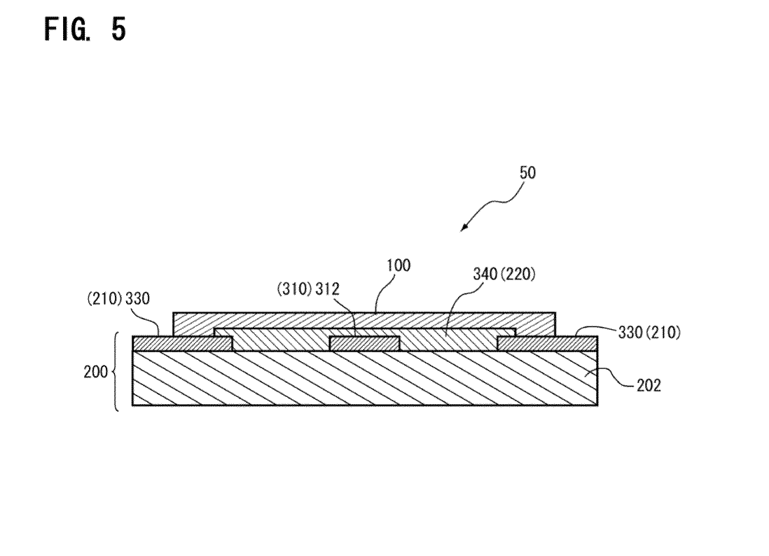

FIG. 4A is a schematic drawing of the touch panel sensor sheet 250 equipped with the circuit board 50 manufactured by the present method. FIG. 4B is an enlarged view of area B in FIG. 4A. FIG. 5 is a cross sectional schematic drawing of the touch panel sensor sheet 250 taken along the Y-axis, and corresponds to a cross sectional view taken along tine V-V in FIG. 4B. The touch panel sensor sheet 250 has draw-out lines 260 respectively drawn out via metallization from a first electrode 300 and a second electrode 320, and an extraction electrode 270 for external connection, connected to the draw-out lines 260.

The circuit board 50 composing the touch panel sensor sheet 250 of this embodiment includes the base 200 and the electroconductive patterns 100 (see FIG. 2D). As illustrated in FIG. 4B and FIG. 5, the base 200 has the first electrode 300 and the second electrode 320 which configure an electroconductive first underlying area, and insulating patterns 340 which configure an insulating second underlying area. Each electroconductive pattern 100 is contiguously formed so as to extend over the second electrode 320 which configures the first underlying area, and the insulating pattern 340 which configures the second underlying area.

More specifically, the base 200 has a transparent sheet 202, the first electrode 300, the second electrode 320 and the insulating patterns 340. The transparent sheet 202 is composed of a visible light transmissive resin material, film glass or the like. All of the first electrode 300, the second electrode 320 and the insulating patterns 340 are formed on one surface of the transparent sheet 202. The first electrode 300, the second electrode 320 and the insulating patterns 340 are provided on the same side of the transparent sheet 202. Each electroconductive pattern 100 is formed on each insulating pattern 340, and more specifically, formed so as to step over the first electrode 300 and the insulating pattern 340. In FIG. 4B, the electroconductive pattern 100 is hatched for the convenience of explanation. The first electrode 300 has a plurality of first electrode patterns 310 repetitively disposed side by side in a first direction (X-direction) and connected with each other. The second electrode 320 has a plurality of second electrode patterns 330 disposed side by side in a second direction (Y-direction) which crosses the first direction, while being spaced from the first electrode patterns 310. Each insulating pattern 340 covers each interconnect 312 of the adjacent first electrode patterns 310. Each electroconductive pattern 100 is formed over each interconnect 312. The electroconductive patterns 100 may be formed on the top surfaces of the interconnects 312, that is, the surfaces of the interconnects 312 opposite to the transparent sheet 202, so as to be brought into direct contact, or may be formed above the interconnects 312 while placing any other layer in between. The electroconductive patterns 100 configure jumper patterns which connect the adjacent second electrode patterns 330.

The first electrode 300 and the second electrode 320 are formed on the surface of the base 200. The first electrode 300 in this embodiment is configured by a plurality of rectangular (rhombic) first electrode patterns 310 connected in succession with the narrower interconnects 312. in the Y-direction, a plurality of rectangular (rhombic) second electrode patterns 330 are discretely arranged to form an assembly. The adjacent second electrode patterns 330 arrayed in the Y-direction are electrically and physically connected through the electroconductive patterns 100. The insulating patterns 340 isolate the electroconductive patterns 100 from the first electrode 300. The electroconductive pattern 100 may have an unillustrated protective film formed thereon by coating.

For the transparent sheet 202, film materials such as highly transparent PET (polyethylene terephthalate) film, polycarbonate film and transparent polyimide film; and thin sheet type glass substrate may be used. The transparent sheet 202 is not specifically limited in terms of thickness, so long as it is flexible. The transparent sheet 202 may have a coated layer formed on the surface thereof, for the purpose of improving adhesiveness to the first electrode 300 and the second electrode 320, and uniformity of coating.

The insulating patterns 340 are obtained typically by preparing an ink or paste using a highly transparent resin material, forming a desired pattern using it by a technique such as ink-jet printing or screen printing, and allowing the pattern to dry or cure by heating or UV irradiation.

The first electrode patterns 310 and the second electrode patterns 330 have transparency and electrical conductivity, and have a sensing function which allows determination of point(s) where the finger(s) of the user came close to, based on changes in electrostatic capacitance which locally changes at the point(s).

The first electrode pattern 310 and second electrode pattern 330 are composed of any of transparent and electroconductive metal materials or resin materials. Examples of the material include metal oxide-based materials represented by ITO (tin-doped indium oxide), ATO (antimony-doped tin oxide) and FTC) (fluorine-doped tin oxide); transparent electroconductive polymer-based materials represented by PEDOT, polypyrrole and polyaniline; and nanowire-based materials having electroconductive nanowires scattered to form an irregular network pattern on the base 200, fixed in a resin. Materials for composing the electroconductive nanowires are exemplified by silver, metal alloy and carbon.

The draw-out lines 260 are metallized interconnects for transmitting position detection signals output from the first electrode patterns 310 and the second electrode patterns 330, to an external board or circuit. The draw-out lines 260 are formed by patterning a sputtered metal foil typically by a photolithographic technique, or formed pattern-wise using an electroconductive paste or ink by a printing technique such as screen printing, gravure printing or flexographic printing.

The insulating patterns 340 electrically isolate the electroconductive patterns 100 from the underlying first electrode patterns 310. The insulating patterns 340 prevent the second electrode patterns 330 and the first electrode patterns 310 from electrically conducting through the electroconductive patterns 100. The insulating patterns 340 have a band form wider in width than the interconnects 312, and extend in the direction (X-direction) in which the first electrode 300 is arrayed. The directions in which the insulating patterns 340 and the electroconductive patterns 100 respectively extend cross each other. As illustrated in FIG. 5, the insulating patterns 340 in this embodiment are formed so as to climb up onto the neighboring edges of the adjacent second electrode patterns 330. The insulating patterns 340 may be formed using any arbitrary insulating materials so long as they are highly transparent. For example, resin materials of heat curable type, heat drying type and UV curable type are preferably used.

Also the electroconductive patterns 100 are preferably transparent, in order to satisfy requirements on transparency of the touch panel sensor sheet 250. For the electroconductive patterns 100, usable is a PEDOT paste which is configured by PEDOT (polyethylene dioxythiophene), a kind of transparent electroconductive polymer-based materials, modified to be adaptive to screen printing.

According to the present method, narrow-width and high-quality electroconductive patterns 100 may be formed, even if the wettability of the electroconductive patterns 100 differs from part to part on the underlying layer, for example on the second electrode patterns 330, the insulating patterns 340 and the transparent sheet 202.

As illustrated in FIG. 5, the base 200 has the second electrode patterns 330 which configure electroconductive first underlying area 210, and the insulating patterns 340 which configure an insulating second underlying area 220. The electroconductive patterns 100 are formed contiguously so as to extend over the first underlying areas 210 and the second underlying area 220.

The electroconductive patterns 100 which compose the jumper patterns may have a form of single line, a form of a plurality of parallel lines, and any other form.

FIG. 6A to FIG. 6B are schematic drawings of the line patterns 20 of the screen printing plate 10, and the electroconductive patterns 100 formed through the screen printing plate 10. The drawings emphasize difference in the line width between the dense areas R1 and the sparse areas R2. As illustrated in FIG. 6A, the line pattern 20 may be configured by an assembly of a plurality of through-holes 30 arrayed in line. By screen printing using the screen printing plate 10 having such line pattern 20 (see FIGS. 1A and 1B), the electroconductive patterns 100 each haying the form of a single line illustrated in FIG. 6B may be formed. Each electroconductive pattern 100 is configured by large-diameter ink dot areas 153 (dense areas R1) corresponded to the ink dots 152 and small-diameter crept ink area 157 (sparse areas R2) corresponded to the crept ink, alternately and repetitively disposed therein.

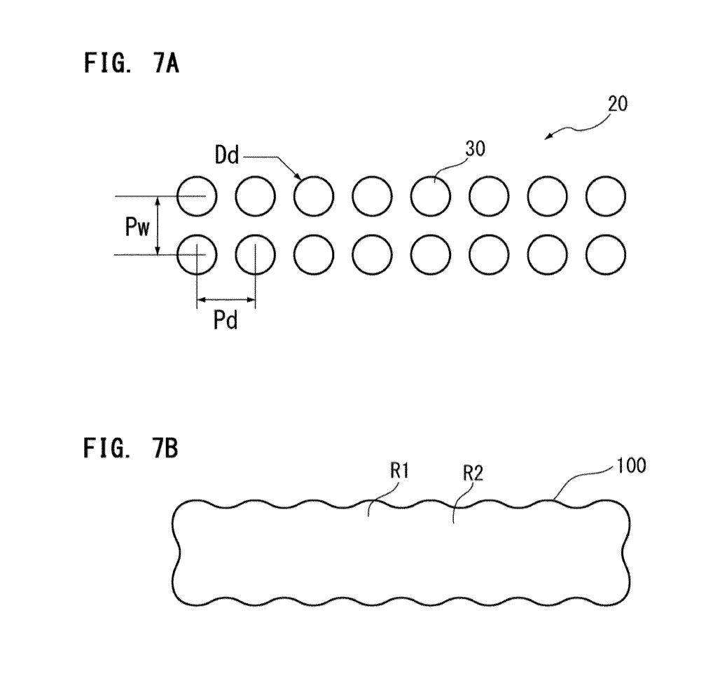

FIG. 7A illustrates another exemplary line pattern 20 configured by the through-holes 30 arrayed in a plurality of lines (a vertical double-row pattern shown in the drawing) to form a grid. As shown in the drawing, the pitch (center-to-center distance) of the through-holes 30 in the linewise direction is now denoted as linewise pitch Pd, and the pitch (center-to-center distance) of the through-holes 30 in the direction orthogonal to the linewise direction is denoted as widthwise pitch Pw. FIG. 7B illustrates the electroconductive pattern 100 having the form of a single line, obtained by allowing a plurality of undried ink dots 152 arrayed in a plurality of lines (see FIG. 3), to fuse respectively in the widthwise direction and the longitudinal direction. The present inventors made clear from our findings that, when the linewise pitch Pd and the widthwise pitch Pw relative to the diameter Dd are not larger than predetermined ratios, and if the thickness Tm of the screen printing plate 10 is not smaller than a predetermined value, the electroconductive pattern 100 is given in the form of a single line from the plurality of line patterns 20. If the widthwise pitch Pw of the through-holes 30 relative to the diameter Dd is not smaller than a predetermined ratio, the electroconductive pattern 100 is given as a plurality of parallel lines.

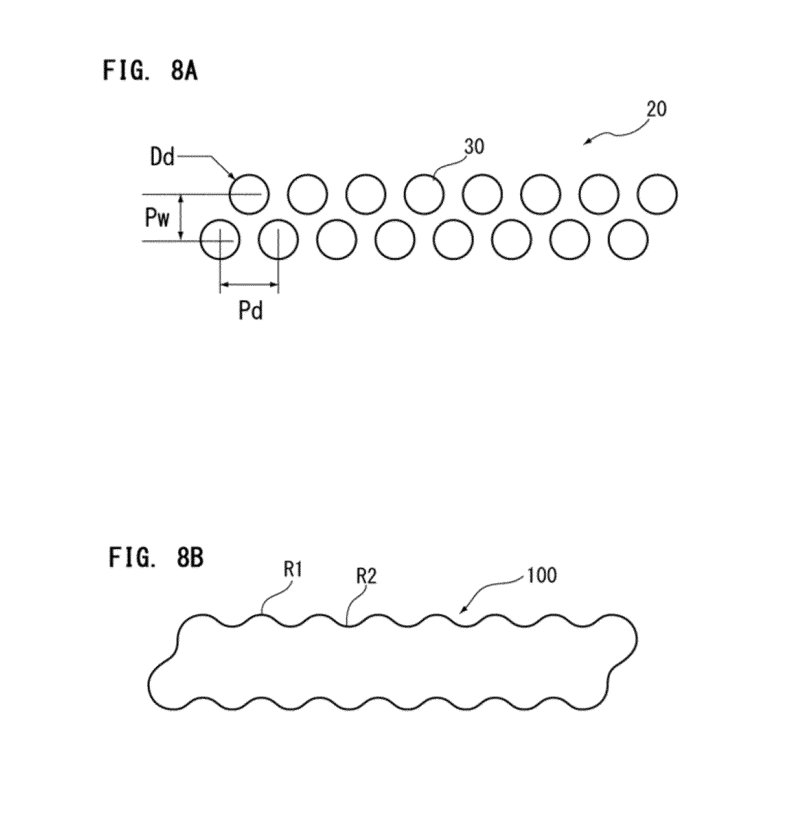

FIG. 8A illustrates another exemplary line pattern 20 configured by the through-holes 30 arrayed in a plurality of lines (a double-row pattern shown in the drawing) in a staggered manner. By the staggered arrangement, the widthwise pitch Pw of the line patterns 20 is preferably reduced, while keeping the distance between the neighboring edges of the through-holes 30 at a certain sufficient value. FIG. 8B illustrates the electroconductive pattern 100 having the form of a single line, obtained by allowing a plurality of ink dots 152 arrayed in a plurality of lines (see FIG. 3), to fuse respectively in the widthwise direction and the longitudinal direction.

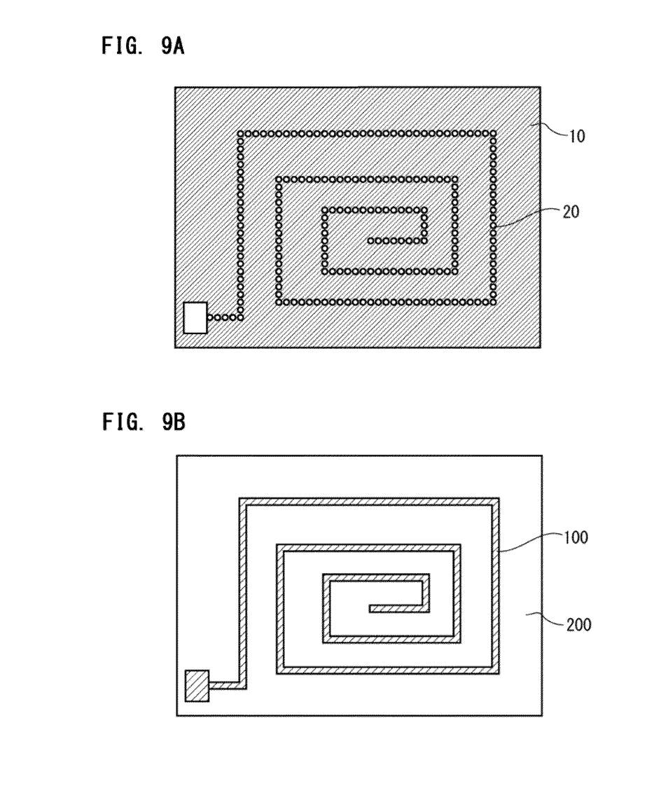

FIG. 9A is a schematic drawing illustrating a first modified example of the screen printing plate 10. FIG. 9B is a schematic drawing illustrating the electroconductive pattern 100 formed on the base 200 using the screen printing plate 10. For the convenience of explanation, the screen printing plate 10 in FIG. 9A and the electroconductive pattern 100 in FIG. 9B are hatched. The screen printing plate 10 is a metal mask having the line pattern 20 formed in a substantially closed loop. The substantially closed loop herein means that three edges of a rectangle surrounding a certain area are closed, or three quarters or more of the circumferential length of the area are closed. The line pattern 20 in this embodiment is given in the for of long strip having a plurality of bend or curved portions. By configuring the line pattern 20 by the discrete through-holes 30, the metal mask substantially remains in a plate form which is continuous both lengthwise and crosswise over the entire portion thereof, enough to retain strength of the screen printing plate 10. For this reason, it is also possible to form the multi-turn spiral electroconductive pattern 100 as illustrated in the drawing, by screen printing using the metal mask.

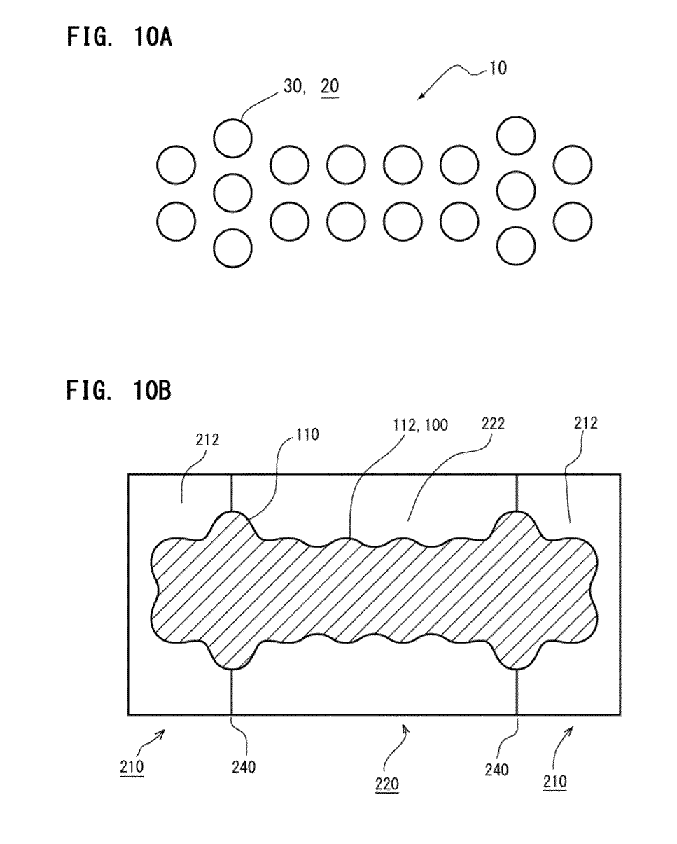

FIG. 10A is a schematic drawing illustrating a second modified example of the screen printing plate 10. FIG. 10B is a schematic drawing of the electroconductive pattern 100 formed on the base 200 using the screen printing plate 10. For the convenience of explanation, the electroconductive pattern 100 is hatched. The base 200 has, exposed to the surface thereof, the first underlying areas 210 and the second underlying area 220 which are different in the wettability.

At boundary zones 240 between the first underlying areas 210 and the second underlying area 220, the electroconductive pattern 100 is widened as compared with intermediate zones 212, 222 of the first underlying areas 210 and the second underlying area 220, respectively. In other words, electroconductive patterns 110 formed at the boundary zones 240 have a width larger than that of the electroconductive pattern 112 formed in the intermediate zone 212 of the first underlying area 210 and in the intermediate zone 222 of the second underlying area 220. In this way, the electroconductive pattern 100 may be relieved from the risk of adhesion failure at the boundary zones 240 where properties of the surface of the underlying layer change, thereby generally improving the adhesiveness and electrical connection between the base 200 and the electroconductive patterns 100. When the electroconductive pattern 110 is widened over the electroconductive pattern 112, the number of through-holes 30 arrayed in the widthwise direction of the line pattern 20 may be increased, or the diameter of the individual through-holes 30 may be enlarged.

The first underlying areas 210 and the second underlying area 220 in this embodiment are contiguously formed, without leaving gaps in between, as illustrated in FIG. 10B. The boundary zone 240 refers to an area with a predetermined width, which includes the boundary between each first underlying area 210 and the second underlying area 220. For the case where a gap zone is formed between each first underlying area 210 and the second underlying area 220, the boundary one 240 refers to an area with a predetermined width, which includes a part of or the entire range of the gap zone. The intermediate zone 212 of the first underlying area 210 is an area other than the boundary zone 240 of the first underlying area 210. The intermediate zone 222 of the second underlying area 220 is an area other than the boundary zone 240 of the second underlying area 270.

### EXAMPLES

The present invention will now be further detailed referring to Examples.

### (Screen Printing Plate)

The electroconductive patterns were formed using each of the screen printing plates 10 having the single-row line pattern (referred to as single-row pattern, hereinafter) illustrated in FIG. 6A, and the double-row line pattern (referred to as double-row pattern, hereinafter) illustrated in FIG. 7A. The screen printing plates used herein were metal masks with a thickness Tm of 20 μm, and the squeegee used herein was a metal squeegee.

The electroconductive patterns were aimed to be linear with a target length of 1000 μm or longer, and a target width of 100 μm to 200 μm or around. For the single-row pattern, eight consecutive through-holes were provided with a diameter Dd of 100 μm and a linewise pitch Pd of 130 μm. For the double-row pattern, ten consecutive through-holes 30 were provided in the linewise direction, with a diameter Dd of 100 μm, a linewise pitch Pd of 130 μm, and a widthwise pitch Pw of 60 μm.

### (PEDOT Paste)

The ink used herein was a PEDOT paste prepared by mixing an aqueous dispersion of a PEDOT-PSS mixture, with a polyolefin resin as a binder, and ethylene glycol as the other additive. The PEDOT paste was adjusted to have a viscosity of 100 cP or above and 1000 cP or below. More specifically, a common PEDOT paste with a viscosity of 1000 cP was used in Example 1 to Example 4 below. The PEDOT paste was found to show a surface tension of liquid surface of 42 mN/m. The viscosity and surface tension of the PEDOT paste were measured at a normal temperature of 23° C. The viscosity of the PEDOT paste may be measured in compliance with JIS Z0803. The surface tension of the PEDOT paste may be measured by the ring method specified by JIS K2241.

### (Underlying Layer)

A transparent electroconductive film was manufactured by scattering, on a PET film, silver nanowires to form an irregular network pattern, followed by fixation, to thereby produce an electroconductive underlying layer. On the other hand, as the insulating underlying layer, a highly-transparent resin paste was applied by printing onto a PET film by applying by printing, with the surface of which remained without adhesion enhancing treatment, the paste was then dried under heating to thereby for a coated film of approximately 3 μm thick.

On the electroconductive underlying layer and insulating underlying layer, the ink was respectively coated through the screen printing plates with the single-row pattern and the double-row pattern described above, to thereby form the electroconductive patterns. Example 1 relates to the electroconductive pattern formed through the single-row pattern onto the electroconductive underlying layer, and Example 2 relates to the electroconductive pattern formed through the single-row pattern onto the insulating underlying layer. Example 3 relates to the electroconductive pattern formed through the double-row pattern onto the electroconductive underlying layer, and Example 4 relates to the electroconductive pattern formed through the double-row pattern onto the insulating underlying layer.

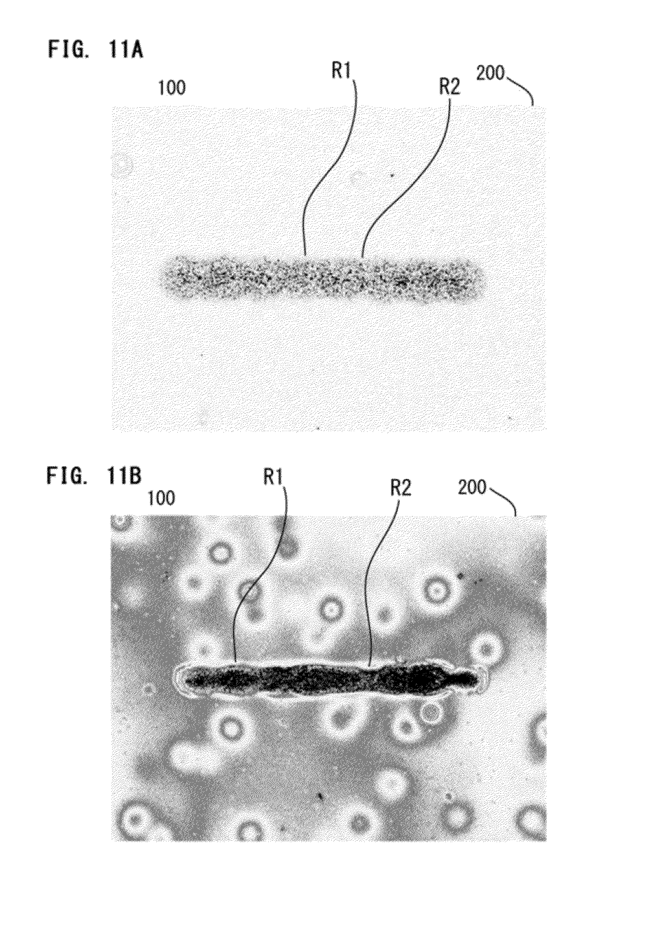

FIG. 11A is a microphotograph of the electroconductive pattern 100 of Example 1, produced by coating the PEDOT paste through the screen printing plate 10 with a single-row pattern onto the electroconductive underlying layer as the base 200. The electroconductive pattern 100 was approximately 1050 μm long and approximately 130 μm wide. The electroconductive pattern 100 was found to satisfy the target dimension and appeared to be a straight line without disconnection, although with some difference in width between the dense areas R1 with a relatively high density of PEDOT grains and the sparse areas R2 with a relatively low density thereof.

FIG. 11B is a microphotograph of the electroconductive pattern 100 of Example 2, produced by coating the PEDOT paste through the screen printing plate 10 with a single-row pattern onto the insulating underlying layer as the base 200. The obtained electroconductive pattern 100 was approximately 1010 μm long and approximately 90 μm wide, appeared as an almost straight line without disconnection. The line width was slightly smaller than the target dimension, showing difference in width between the dense areas RI with a relatively high density of PEDOT grains and the sparse areas R2 with a relatively low density thereof. In other words, the insulating underlying layer was found to be inferior to the electroconductive underlying layer in terms of wettability of the PEDOT paste, which caused liquid migration and made the electroconductive pattern 100 more likely to be thinned. The electroconductive pattern 100 formed in Example 2 was, however, found to keep the width thereof at a level as much as approximately 70% (≈90 μm/130 μm) of the line width in Example 1. It was also found that, even if the insulating underlying layer should have fine irregularities on the surface thereof, the electroconductive pattern 100 free from disconnection was successfully formed without being affected by such surface conditions.

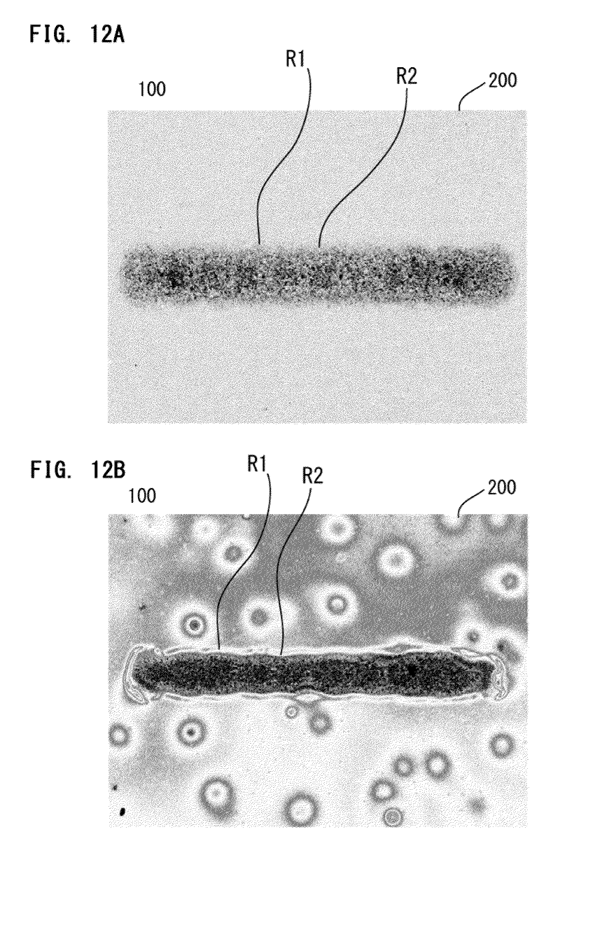

FIG. 12A is a microphotograph of the electroconductive pattern 100 of Example 3, produced by coating the PEDOT paste through the screen printing plate 10 with a double-row pattern onto the electroconductive underlying layer as the base 200. The electroconductive pattern 100 was approximately 1340 μm long and approximately 190 μm wide. Almost no difference in width was observed between the dense areas R1 with a relatively high density of PEDOT grains and the sparse areas R2 with a relatively low density thereof. The electroconductive pattern 100 was found to satisfy the target dimensions, and appeared to be a good straight line without disconnection.

FIG. 12B is a microphotograph of the electroconductive pattern 100 of Example 4, produced by coating the PEDOT paste through the screen printing plate 10 with a double-row pattern onto the insulating underlying layer as the base 200. The electroconductive pattern 100 was approximately 1300 μm long and approximately 160 μm wide. Almost no difference in width was observed between the dense areas R1 with a relatively high density of PEDOT grains and the sparse areas R2 with a relatively low density thereof. The electroconductive pattern 100 was found to satisfy the target dimensions, and appeared to be a good straight line without disconnection.

It was found from Examples above that the linear, narrow-width electroconductive patterns were successfully formed using whichever of the single-row pattern and the double-row pattern, by electing the PEDOT paste to form the discrete ink dots, and then allowing the ink dots to fuse with each other to form a linear ink puddle. In particular from the results of Examples 3 and 4, it was found that, by using the multi-row line pattern, the linear electroconductive patterns with the target dimensions were successfully formed, not only on the electroconductive underlying layer with a good wettability to the PEDOT paste, but also on the insulating underlying layer with a poor wettability.

By coating the ink respectively on the electroconductive underlying layer and the insulating underlying layer, which largely differ in wettability to the water-based ink, the electroconductive patterns having close values of width were formed. More specifically, the line width in Example 1 was approximately 130 μm, and the line width in Example 2 was approximately 90 μm, which was approximately 70% of the line width in Example 1. It is understood from the results that, when the narrow-width electroconductive patterns 100 of 100 μm wide or around are formed so as to extend over both of the electroconductive underlying layer and the insulating underlying layer, the linear electroconductive patterns are successfully formed without disconnection, by coating the PEDOT paste so as to form consecutive dots.

While the PEDOT was used in Example 1 and Example 2 above, the principle of the present invention is also applicable to the case where any other water-dispersed electroconductive paste is used as the ink. While the underlying layers on which the ink is coated were exemplified by the electroconductive underlying layer and the insulating underlying layer, the present invention is not limited thereto. It is to be understood that the present invention is preferably used also when the linear electroconductive patterns are formed so as to extend over the electroconductive underlying layers having different levels of wettability, or over both of the insulating underlying layers having different levels of wettability.

The embodiments and Examples described above also embrace the technical ideas below.

(1) A method of manufacturing a circuit board, the method includes: establishing stand-by by setting a screen printing plate so as to be opposed with a base, the screen printing plate having a line pattern formed therethrough, and the line pattern being configured by a plurality of dot-like through-holes discretely pierced and arrayed in a single line or in a plurality of lines; coating an ink which contains a water-dispersed electroconductive paste onto the surface of the screen printing plate;

ejecting the ink through the dot-like through-holes onto the surface of the base, by pressing the screen printing plate onto the base under sliding contact of a squeegee with the surface of the screen printing plate, and allowing ink dots ejected out from the adjacent through-holes to fuse on the surface of the base, to thereby form a linear ink puddle; and drying the linear ink puddle to form an electroconductive pattern on the surface of the base.

(2) The method of manufacturing a circuit board of (1), wherein in the step of ejecting the ink, a portion of the ink, ejected from the through-hole and creeps forward in the direction of sliding contact of the squeegee into a gap between the screen printing plate and the base, is allowed to fuse with the ink dot(s) ejected cut through the other through-hole(s) adjacent in the direction of sliding contact.

(3) The method of manufacturing a circuit board of (1) or (2) implemented by using the screen printing plate having a line pattern formed therethrough, the line pattern being configured by a plurality of clot-like through-holes discretely pierced in a plurality of lines arrayed in the widthwise direction, wherein in the step of electing the ink, the ink dots ejected from the through-holes arrayed in the widthwise direction are allowed to fuse to form a single linear ink puddle.

(4) The method of manufacturing a circuit board of any one of (1) to (3), wherein the ink dot ejected from the through-hole is allowed to fuse with another ink dot, based on diffusion with the aids of wettability on the surface of the base and creepage on the back surface side of the through-hole.

(5) The method of manufacturing a circuit board of any one of (1) to (4), wherein Formula (1) below holds, with thickness Tm of the screen printing plate, diameter Dd of the through-hole, and center-to-center distance P1 of the through-holes adjacent in the travel direction of the squeegee:

2.5×Tm≧P1−Dd>0 Formula (1).

(6) The method of manufacturing a circuit board of any one of (1) to (5), wherein the water-dispersed electroconductive paste contains an organic electroconductive polymer dispersed in a water-based solvent.

(7) The method of manufacturing a circuit hoard of (6), wherein the organic electroconductive polymer is polyethylene dioxythiophene, polyaniline or polypyrrole.

(8) A circuit board which includes an electroconductive pattern composed of an organic electroconductive polymer, formed in a line pattern, the electroconductive pattern having dense areas and sparse areas alternately disposed repetitively in the longitudinal direction of the electroconductive pattern, the dense areas having, when counted in the widthwised direction, a large number of grains of the organic electroconductive polymer, and the sparse areas having a small number of grains.

(9) The circuit board of (8), wherein the electroconductive pattern has a widthwise dimension of 300 μm or smaller.

(10) The circuit board of (8) or (9), wherein the base has an electroconductive first underlying area and an insulating second underlying area, and the electroconductive pattern is contiguously formed so as to extend over the first underlying area and the second underlying area.

(11) The circuit board of (10), wherein the electroconductive pattern is widened at a boundary between the first underlying area and the second underlying area, as compared to that in an intermediate zone of the first underlying area or of the second underlying area.

(12) A touch panel sensor sheet which includes the circuit board described in (10) or (11), the base includes a flexible transparent sheet composed of a visible light transmissive material; and a first electrode and a second electrode which configure a first underlying area, and an insulating pattern which configures a second underlying area, both areas being formed on one surface of the transparent sheet, the first electrode containing a plurality of first electrode patterns arrayed repetitively in a first direction, the second electrode containing a plurality of second electrode patterns arrayed in a second direction which crosses the first direction, while being spaced from the first electrode patterns, the insulating pattern covering an interconnect between the adjacent first electrode patterns, and the electroconductive pattern configuring a jumper pattern which connects the adjacent second electrode patterns.

(13) A screen printing plate having a line pattern formed therethrough, the line pattern being configured by a plurality of dot-like through-holes discretely pierced and arrayed in a single line or in a plurality of lines.

(14) The screen printing plate of (13), configured as a metal mask having the line pattern formed in a substantially closed loop.

It is apparent that the present invention is not limited to the above embodiment, and may be modified and changed without departing from the scope and spirit of the invention.

What is claimed is:

1. A method of manufacturing a circuit board, the method comprising:
establishing stand-by by setting a screen printing plate so as to be opposed with a base, the screen printing plate having a line pattern formed therethrough, and the line pattern being configured by a plurality of dot-like through-holes discretely pierced and arrayed in a single line or in a plurality of lines;
coating an ink which contains a water-dispersed electroconductive paste onto the surface of the screen printing plate;
ejecting the ink through the dot-like through-holes onto the surface of the base, by pressing the screen printing plate onto the base under sliding contact of a squeegee with the surface of the screen printing plate, and allowing ink dots ejected out from the adjacent through-holes to fuse on the surface of the base, to thereby form a linear ink puddle; and
drying the linear ink puddle to form an electroconductive pattern on the surface of the base.

2. The method of manufacturing a circuit board of claim 1,
wherein in the step of ejecting the ink, a portion of the ink, elected from the through-hole and creeps forward in the direction of sliding contact of the squeegee into a gap between the screen printing plate and the base, is allowed to fuse with the ink dot ejected out through the other through-hole adjacent in the direction of sliding contact.

3. The method of manufacturing a circuit board of claim 1, implemented by using the screen printing plate having a line pattern formed therethrough, the line pattern being configured by a plurality of dot-like through-holes discretely pierced in a plurality of lines arrayed in the widthwise direction,
wherein in the step of ejecting the ink, the ink dots ejected from the through-holes arrayed in the widthwise direction are allowed to fuse to form a single linear ink puddle.

4. The method of manufacturing a circuit board of claim 1,
wherein the ink dot ejected from the through-hole is allowed to fuse with another ink dot, based on diffusion with the aids of wettability on the surface of the base and creepage on the back surface: side of the through-hole.

5. The method of manufacturing a circuit board of claim 1,
wherein Formula (1) below holds, with thickness Tm of the screen printing plate, diameter Dd of the through-hole, and center-to-center distance P1 of the through-holes adjacent in the travel direction of the squeegee:
5×Tm≧P1−Dd>0 Formula (1).

6. The method of manufacturing a circuit board of claim 1,
wherein the water-dispersed electroconductive paste contains an organic electroconductive polymer dispersed in a water-based solvent.

7. The method of manufacturing a circuit board of claim 6,
wherein the organic electroconductive polymer is polyethylene dioxythiophene, polyaniline or polypyrrole.

8. A circuit board comprising an electroconductive pattern composed of an organic electroconductive polymer, formed in a line pattern,
the electroconductive pattern having dense areas and sparse areas alternately disposed repetitively in the longitudinal direction of the electroconductive pattern, the dense areas having, when counted in the widthwised direction, a large number of grains of the organic electroconductive polymer, and the sparse areas having a small number of grains.

9. The circuit board of claim 8,
wherein the electroconductive pattern has a widthwise dimension of 300 μm or smaller.

10. The circuit board of claim 8,
wherein the base has an electroconductive first underlying area and an insulating second underlying area, and the electroconductive pattern is contiguously formed so as to extend over the first underlying area and the second underlying area.

11. The circuit board of claim 10,
wherein the electroconductive pattern is widened at a boundary between the first underlying area and the second underlying area, as compared to that in an intermediate zone of the first underlying area or of the second underlying area.

12. A touch panel sensor sheet comprising the circuit board described in claim 10,
the base comprising:
a flexible transparent sheet composed of a visible light transmissive material; and
a first electrode and a second electrode which configure a first underlying area, and an insulating pattern which configures a second underlying area, both areas being formed on one surface of the transparent sheet,
the first electrode containing a plurality of first electrode patterns arrayed repetitively in a first direction and connected with each other,
the second electrode containing a plurality of second electrode patterns arrayed in a second direction which crosses the first direction, while being spaced from the first electrode patterns,
the insulating pattern covering an interconnect between the adjacent first electrode patterns, and
the electroconductive pattern being formed above the interconnect, so as to configure a jumper pattern which connects the adjacent second electrode patterns.

13. A screen printing plate having a line pattern formed therethrough, the line pattern being configured by a plurality of dot-like through-holes discretely pierced and arrayed in a single line or in a plurality of lines.

14. The screen printing plate of claim 13, configured as a metal mask having the line pattern formed in a substantially closed loop.
